(19) United States
(12) Patent Application Publication
(10) Pub. No.: US 2025/0318092 A1
(43) Pub. Date: Oct. 9, 2025

(54) MULTI-PORT HEAT SINK ARRANGEMENT

(71) Applicant: Honeywell International Inc, Charlotte, NC (US)

(72) Inventor: Winfred Morgan Reed, Benton, KY (US)

(21) Appl. No.: 19/097,763

(22) Filed: Apr. 1, 2025

Related U.S. Application Data
(60) Provisional application No. 63/631,316, filed on Apr. 8, 2024.

(51) Int. Cl. H05K 7/20

(52) U.S. Cl. CPC H05K 7/20927

(57) ABSTRACT

A heat exchange device for electrical applications comprising a body comprising a thermally conductive material and including one or more passages disposed substantially parallel about a longitudinal axis of the body, and one or more tubes comprising a corrosion resistant material, different from the thermally conductive material, each of the one or more tubes disposed within a respective passage.

### CLAIM OF PRIORITY

This application claims priority to U.S. Provisional Patent Application No. 63/631,316 entitled “MULTI-PORT HEAT SINK ARRANGEMENT”, filed on Apr. 8, 2024, the entire disclosure of which is incorporated by reference in its entirety herein.

### FIELD OF THE INVENTION

The present invention relates to heat sinks, and specifically, liquid cooled heat sinks used to cool high power equipment such as silicon-controlled rectifiers (SCRs).

### BACKGROUND

Heat exchangers, and in some cases, liquid cooled heat exchangers, often referred to as liquid cooled heat sinks or chill blocks, can be used to maintain the temperature of electrical equipment. However, liquid cooled heat sinks encounter numerous issues when applied in such contexts, which detrimentally effect the operability and/or serviceability of the heat sink, such as issues attributable to galvanic corrosion. What is needed is a liquid cooled heat sink that resolves such deficiencies.

### SUMMARY

The present disclosure provides a liquid cooled heat sink that includes one or more, and particularly two tubes comprising an anticorrosive material (e.g., stainless steel) disposed within two passages formed in a body of the heat sink formed of a thermally conductive material (e.g., copper). The two tubes extend from the body of the heat sink, and are fluidly coupled to one another outside the body. Such arrangement substantially eliminates issues attributable to galvanic corrosion. The heat sink may optionally include multiple features to enhance the serviceability/operability of the heat sink.

In a first embodiment of the present disclosure, a heat exchange device for electrical applications is provided. The heat exchange device may comprise a body comprising a thermally conductive material and including one or more passages disposed substantially parallel about a longitudinal axis of the body; and one or more tubes comprising a corrosion resistant material, different from the thermally conductive material, each of the one or more tubes disposed within a respective passage.

In another embodiment of the present disclosure, an electrical equipment system is provided. The electrical system may comprise a heat-generating electrical component, and a heat sink in thermal communication with the electrical component. The heat sink may comprise a body comprising a thermally conductive material and including two passages arranged in tandem and disposed substantially parallel about a longitudinal axis of the body; and two tubes comprising a corrosion resistant material, different from the thermally conductive material, each of the two tubes disposed within a respective passage and extending from the respective passage at a first end and a second end, each of the first ends and the second ends in fluid communication external to the body of the heat sink.

### BRIEF DESCRIPTION OF DRAWINGS

FIG. 1 illustrates an embodiment of a heat sink that encounters numerous corrosion-related issues.

FIG. 2 illustrates a perspective view of an embodiment of a heat sink described in the present disclosure.

FIG. 3 illustrates a top-down view of the embodiment of the heat sink illustrated in FIG. 2.

FIG. 4 illustrates an exemplary water cooled assembly including SCRs.

### DETAILED DESCRIPTION

The present disclosure relates to heat sinks, and particularly liquid-cooled heat sinks, also known as chill blocks, used to cool high-heat generating electrical equipment, such as silicon-controlled rectifiers (SCRs) used in high-power applications, including in the production of industrial chemicals such as fluorine gas.

Gaseous chemicals, such as gaseous fluorine, may be produced by a variety of methods, including by electrolysis/electrolytic oxidation. For instance, anhydrous hydrogen fluoride (HF) may be converted by electrolytic oxidation to yield hydrogen (H₂) gas and fluorine (F₂) gas, where the amount of current applied to the anode of the electrolytic cell is proportional to the amount of gaseous fluorine evolved by the process. The industrial-scale generation of fluorine gas therefore necessitates the use of high electrical currents to supply power to the many electrolytic cells used to produce the fluorine gas by electrolytic oxidation.

In electrolytic cells, DC power is applied to an anode, causing electrons to flow from the anode to the cathode of the electrolytic cell, facilitating controlled chemical transformations, such as the controlled conversion of HF to F₂ and H₂. Electrolysis requires the use of direct current (DC), necessitating the conversion of alternating current (AC) to direct current (DC) being supplied to the electrolytic cells.

Alternating current is commonly converted to direct current by electrical rectifiers. Rectifiers are electronic devices that convert alternating current into direct current by allowing the flow of electric current in one direction, resulting in a unidirectional flow of pulsating direct current. Common forms of rectifiers include diodes and thyristors. One type of thyristor is a silicon-controlled rectifier (SCR). Silicon controlled rectifiers are semiconductor devices that act as a controlled switch, allowing current to flow in one direction when triggered by a small voltage at its gate. Widely used in power control applications, SCRs are particularly suited for high-power systems, where they enable precise control over the flow of DC electrical current to the connected device(s). Accordingly, SCRs are commonly used as the preferred method to control the conversion of AC power to DC power in high-power industrial-scale operations, including in electrolytic oxidation processes.

During operation, SCRs generate a large amount of thermal energy due to the resistance of the semiconductor material generating heat, increasing the temperature of the SCR during the switching of electrical circuits. The heat generated during operation can exceed the maximum junction temperature the SCR, and therefore, SCRs require precise temperature control.

The temperature of the SCR is often controlled by the use of a heat exchanger, which may be referred to as a heat sink or a cooling block. Heat sinks remove heat from an SCR, allowing for the SCR to operate properly. Specifically, as the SCR generates heat during operation, the heat sink maintains a lower temperature, providing a temperature differential between the heat sink and the SCR, inducing conductive heat transfer away from the SCR material, therefore lowering the operational temperature of the SCR itself.

The thermal energy absorbed by the heat sink must be removed in order to maintain the temperature differential between the SCR and the heat sink. Heat sinks may rely on a variety of cooling methods to remove the thermal energy absorbed by the heat sink including convective-type methods (e.g., natural or forced air-cooling) and/or conductive-type cooling, and particularly-liquid type cooling. Liquid-type cooling is primarily used in high-power SCR applications, as air-cooling may not provide the requisite heat removal rate necessary to cool high-power SCRs.

Liquid-type cooling uses a cooling fluid, such as water or other suitable heat exchange fluid, that flows through a fluid channel in the body of the heat sink, therefore removing excess heat from the heat sink through the conductive heat transfer to the heat exchange fluid.

However, liquid-cooled heat sinks may encounter numerous challenges when applied in high-power electrical equipment applications. For instance, galvanic corrosion, also known as bi-metallic corrosion, occurs when dissimilar metals are in contact in the presence of an electrolyte. As relating to liquid cooled heat sinks, the body of the heat sink is often formed of a first metal, and the connection points to the fluid channels are often formed of a second metal. The cooling fluid (e.g., water) acts as an electrolyte, and therefore, galvanic corrosion occurs between the two dissimilar metals used in the conduction path of the heat sink in the presence of the electrolytic cooling fluid. For instance, in the case where the body is formed of copper, and the fluid connection points are formed of brass, the water passing through the fluid channels causes the brass fitting to corrode, leading to decomposition of the fittings and fouling of the fluid channel.

To prevent galvanic corrosion, at least the fluid channel, and often times the entire heat sink, is coated with an anti-corrosion coating. However, during operation, the coating degrades within the fluid channel (e.g., due to the flow of the cooling fluid) which may disrupt fluid flow (e.g., by the coating flaking off/becoming dislodged from the fluid channel) and once degraded, the fluid channel experiences galvanic corrosion and downstream operations may be effected (e.g., due to the flaking coating and/or dislodged corrosive buildup effecting downstream equipment). In this case, the fluid channel must be thoroughly cleaned to remove corrosion. However, given that the anti-corrosive coating is often a relatively soft material (e.g., zinc/zinc alloy), cleaning the fluid channel further damages the applied coating, exacerbating/furthering the coatings' degradation. Moreover, the internal geometry of the fluid passage is often times complex, which makes cleaning the fluid passage difficult, if not impossible.

Each of these issues leads to the eventual decommissioning and replacement of the heat sink, which not only necessitates significant expense associated with the heat sinks replacement (e.g., a new unit and associated installation costs), but also leads to down time for the connected equipment associated with the defective heat sink, detrimentally effecting the overall up-time of the associated unit operation (e.g., effecting production).

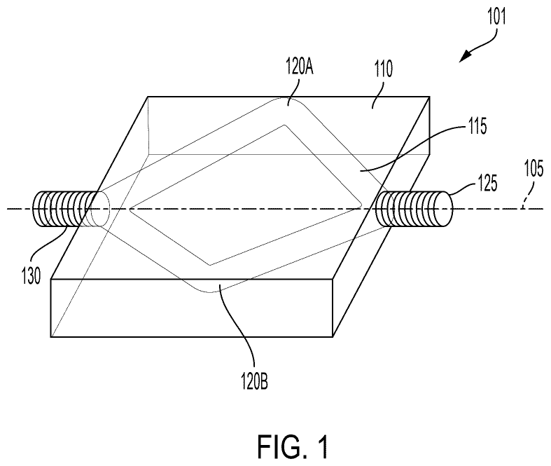

FIG. 1 illustrates a heat sink 101 that may experience such difficulties. For instance, heat sink 101 includes a fluid channel 115 formed within a body 110 of fluid channel 115. Fluid channel 115 is arranged in a diamond-like configuration about a longitudinal axis 105 of heat sink 101, and includes bends 120 A and 120 B. Cooling fluid flows into fluid channel 115 through first fitting 125 and out of fluid channel 115 through second fitting 130, where both of fittings 125 and 130 are integrally formed onto body 110 of heat sink 101.

As described previously, body 110 is formed of a first metal, such as copper, and fittings 125 and 130 are each formed of a second metal, such as brass. In this case, galvanic corrosion occurs between the copper of the body 110 and brass of the fittings 125/130 in the presence of the electrolytic cooling fluid (e.g., water). Therefore, a corrosion resistant coating, such as zinc, is often applied to the entire heat sink 101 to prevent galvanic corrosion. However, the coating often poorly adheres to the complex geometry of fluid passage 115, and particularly at bends 120A/B. Further, cleaning of the complex geometry of fluid passage 115 is difficult, if not impossible without damaging or even destroying the coating applied to the fluid channel (e.g., bends 120A/B being particularly difficult to clean). Accordingly, heat sink 101 experiences significant galvanic corrosion, is difficult to clean, and results in a low useable life of heat sink 101. A process utilizing multiple heat sink 101s to cool high powered electrical equipment, such as the many SCRs used in the electrolytic oxidative production of HF, therefore experiences significant down time and expense due to the constant need to replace damaged heats sink 101s. The present heat sink resolves such deficiencies while also enhancing the serviceability and operability of the heat sink.

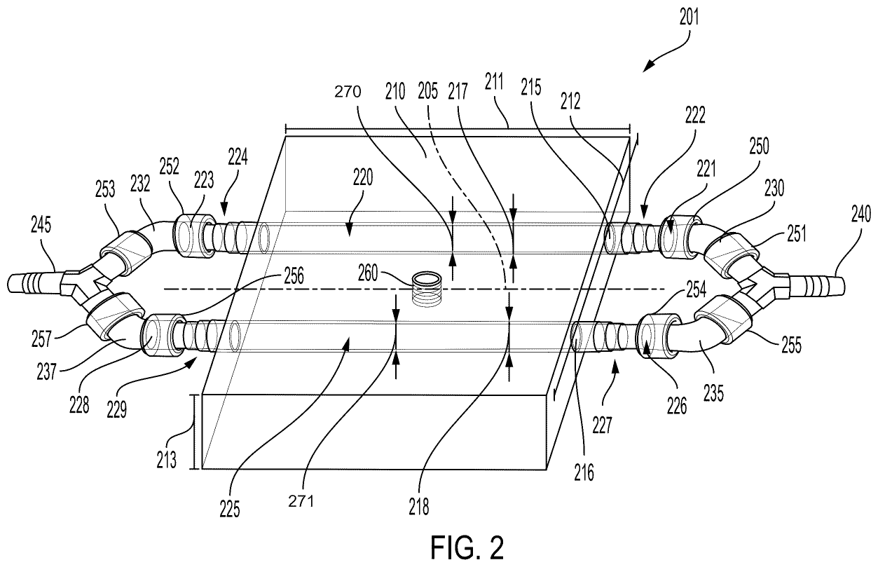

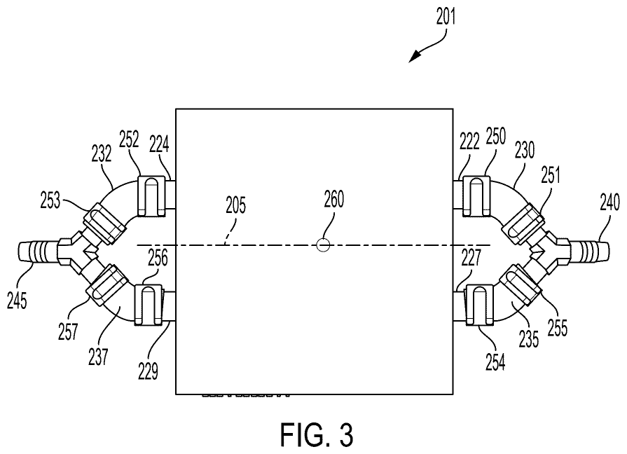

FIG. 2 illustrates a perspective view of heat sink 201 and FIG. 3 illustrates a top-down view of heat sink 201. Heat sink 201 includes body 210, which is formed from a thermally conductive material. Suitable examples of thermally conductive materials include thermally conductive metals such as copper, silver, gold, platinum, and/or alloys thereof. Specifically, the thermally conductive material may be selected based upon a desired thermal conductivity such as a thermal conductivity as low as 100 W/(mK), or as high as 500 W/(mK), and particularly from 350 W/(mK) to 400 W/(mK). The body 210 of heat sink 201 is illustrated as a rectangular prism/cuboid geometry comprising each of length 211, width 212, and height 213. Each of length 211, width 212, and height 213 may be selected upon a variety of factors including the size of the electrical component upon which the body 210 of heat sink 201 is in contact (e.g., the size of the SCR) and/or a desired heat transfer rate (e.g., heat flux) required to cool the electrical component. For instance, each of length 211, width 212, and height 213 may be as little as 0.5 cm to as large as 10 cm, as based upon any of the foregoing factors. More particularly, length 211 may be as little as 3.0 cm to as large as 5.0 cm, width 212 may be as little as 3.0 cm to as large as 5.0 cm, and height 213 may be as little as 0.5 cm to as large as 1.0 cm. Furthermore, although depicted in a rectangular prism orientation, any suitable geometry may be selected based upon the desired use of heat sink 201 (e.g., conforming to the size of the associated electrical equipment/heat flux/etc.).

Heat sink 201 includes a pair of (e.g., two of) passages 215 and 216. Passages 215 and 216 are arranged alongside one another (e.g., in tandem), and may be spaced substantially equidistant from one another and the external boundary of body 210 (e.g., the center lines of passages 215 and 216 being spaced equidistant from the external boundaries of length 211 of body 210). Passages 215 and 216 may also be arranged to be substantially parallel to a longitudinal axis 205 of heat sink 201. However, although described as a longitudinal axis 205, axis 205 can be defined about any longitudinal or transverse axis in relation to a point of body 211, and particularly, when body 210 comprises a nonrectangular prism geometry.

The foregoing arrangement may be regarded as a dual port arrangement (e.g., two ports), and particularly, a “double-pass strait-through” arrangement (e.g., two, one-way flow passages, arranged in a substantially strait orientation). Each of passages 215 and 216 comprise internal diameters 217 and 218 respectively. As will be described in further detail herein, the size of internal diameters 217 and 218 may be determined based upon a desired heat flux from body 210 of heat sink 201 to the cooling fluid resulting in a desired overall heat transfer rate. For instance, diameters 217 and 218 may be as little as 0.25 cm to as large as 1.0 cm, and more particularly, between 0.4 cm and 0.6 cm, and still more particularly, approximately 0.5 cm. Passages 215 and 216 may be subtractively manufactured from the body 210 of heat sink 201, such as by a milling/boring machining process, whereas diameters 217 and 218 are subtractively manufactured from a solid block of material and to a low tolerance between 0.0001 cm and 0.10 cm. More particularly, passages 215 and 216 may be manufactured to a .01 mm tolerance. A low tolerance in the subtractive manufacturing process is used to ensure that the heat transfer between the body 210 of heat sink 201 and the tubes 220 and 225, as will described in further detail herein, is maximized.

Heat sink 210 may include tubes 220 and 225. Tubes 220 and 225 may be formed from a corrosion-resistant material that is different from the material of the body 210 of heat sink 201. The composition of tubes 220 and 225 may be selected based upon resistance to corrosion that occurs due to flowing fluid, which importantly, does not rely on the use of a corrosion resistant coating. Such compositions may include metals, such as those including iron, chromium, nickel, and other alloying elements, and particularly stainless-steel compositions including 304 stainless steel.

Tubes 220 and 225 are inserted into the passages 215 and 216 of body 210, and cooling fluid flows strait through each of tubes 220 and 225. Here, the entrances and exits of tubes 220 and 225 extend from body 210 of heat sink 201, and are coupled to one another, such as via a hose and three-way fitting arrangement as will describe in further detail herein, at respective first ends and second ends, which occurs outside of the body 210 of heat sink 201. Thereafter, a heat exchange fluid, such as water (e.g., deionized water, soft water, etc.) flows through tubes 220 and 225, from the first end to the second end of the tubes, cooling the body 210 of heat sink 201.

Each of tubes 220 and 225 comprise external diameters 270 and 271 respectively where the diameters 270 and 271 may be selected as based upon a desire heat transfer rate between the cooling fluid and the body 210 of heat sink 201. For instance, diameters 270 and 271 of tubes 220 and 225 may be selected on a desired heat transfer rate as based upon the cooling fluid flowrate and temperature differential observed between the cooling fluid and body 210, which in turn drives the thermal flux through body 210 to the cooling fluid. The thermal flux to heat sink 210 determines how much thermal energy (e.g., heat) can be removed from the associated high-power equipment (e.g., SCR). Therefore, diameters 270 and 271 are used to determine the size of diameters 217 and 218 of first passage 215 and second passage 216 respectively, as based upon a desired heat transfer rate.

As with passages 215 and 216, the diameters 270 and 271 of tubes 220 and 225 may be manufactured to low tolerances. Specifically, and similar to passages 215 and 216, tubes 220 and 225 may be subtractively manufactured from a stock of materials, such as a rod of metal (e.g., 304 stainless steel). Here, the external diameters 270 and 271 are manufactured to a low tolerance between 0.0001 cm and 0.10 cm tolerance, and more particularly manufactured to a .01 mm tolerance.

The low tolerances utilized in the manufacturing process allows for the external diameter 270 of first tube 220 to precisely fit within the internal diameter 217 of first passage 215, such that the external diameter 270 of first tube 220 is within 0.01 cm to .0001 cm of internal diameter 217 of first passage 215, and more particularly, within 0.005 cm to 0.002 cm. Similarly, the external diameter 271 of second tube 225 precisely fits within the internal diameter 218 of second passage 216 such that the external diameter 271 of second tube 225 is within 0.01 cm to .0001 cm of internal diameter 218 of second passage 216, and more particularly, within 0.005 cm to 0.002 cm. Here, the low tolerances between the internal diameters 217 and 218 of passages 215 and 216 and the external diameters 270 and 271 of tubes 220 and 225 enhances the observed heat transfer rate between the cooling fluid and body 210. Specifically, given that the tubes external diameters 270/271 are precisely manufactured to fit within the passage internal diameters 217/218, little to no void is formed between tubes 220/225 and passages 215/216, preventing thermally insulative fluids, such as air, from inhibiting the thermal flux between the heat transfer fluid and the body 210. The tight manufacturing enables the use of a single material in the conduction path of heat sink 201, as compared with subtractively manufacturing a conduction path from the body of the heat sink and applying a corrosion resistant coating. Moreover, since tubes 220 and 225 comprise a tube of material, the tubes are replaceable in the event that either one or, or both of the tubes 220/225 are damaged/foul.

Although described in view of a double pass, strait-through arrangement heat comprising two passages 215 and 216 and corresponding tubes 220 and 225, the present disclosure is non-limiting. Specifically, the present disclosure also encompasses heat sinks including one (e.g., single port/single pass strait-through arrangement), three (three-port/triple pass-strait through arrangement), or any suitable number (e.g., multi-port/multi-pass, strait through arrangement) of passages/tubes. Therefore, all of the foregoing and subsequent discussion, including the materials of construction, manufacturing methods (e.g., tight tolerances), and general overall orientation of heat sink 201 applies equally to alternative embodiments, which although not illustrated, are contemplated by the present disclosure.

As based upon the foregoing discussion, the disadvantages of heat sinks similar to heat sinks 101 are alleviated, if not eliminated. For instance, since the tubes 220 and 225 comprise a single anti-corrosive material, galvanic corrosion is essentially eliminated. Specifically, since the conduction path does not comprise multiple dissimilar materials/metals (e.g., the copper and brass of heat sink 101), but a single anti-corrosive metal (e.g., 304 stainless steel) galvanic corrosion does not occur. Furthermore, since the conduction path does not include an anti-corrosive coating, coating degradation concerns (e.g., effecting flow/downstream operations) are essentially eliminated. Still further, since tubes 220 and 225 are arranged in a substantially straight-through arrangement, heat sink 201 can easily be cleaned/serviced. Finally, in the event that tubes 220 and/or 225 need to be replaced, the tubes can be removed from body 210 and replaced with new tubes. Each consideration individually, and particularly in combination, resolves the common issues associated with liquid-cooled heat sinks applied in high-power contexts.

Heat sink 201 may also include additional features that enhance the serviceability and operability of the heat sink. As describe previously, tubes 220 and 225 may extend from passages 215 and 216 of body 210, respectively. Here, such extension may comprise a fitting for fluidly coupling the first and second ends of tubes 220/225 with one another. For instance, the tubes 220 and 225 may include barb-type fittings integrally formed onto opposite ends of tubes 220 and 225 (e.g., first barb type fitting 222 formed on first end 221 of first tube 220 and second barb type fitting 224 formed on second end 223 of first tube 220; and first barb fitting 227 formed on first end 226 of second tube 225 and second barb type fitting 229 formed on second end 228 of second tube 225). Barb type fittings 222, 224, 227, and 229 each allow for connecting hoses 230, 232, 235, and 237 respectively, which serve as the supply (e.g., hoses 230 and 235) and return (e.g., hoses 232 and 237) lines for the cooling fluid. Although described and illustrated as barb-type fittings, any other suitable geometry for fittings may be used to secure tubes 220 and 225 to hoses 230, 232, 235, and 237.

Each of hoses 230, 232, 235, and 237 may be connected to a three-way fitting, such as Y-type connections 240 and 245, coupling each of first ends 221 and 226 of first tube 220 and second tube 225 and second ends 223 and 228 of first tube 220 and second tube 225. Specifically, hose 230 may be coupled to first end 221 of tube 220 via fitting 250 and coupled to Y-type fitting 240 via fitting 251. Hose 235 may also be coupled to first end 226 of tube 225 via fitting 254 and coupled to Y-type fitting 240 via fitting 255. Therefore, the first ends 221 and 226 of tubes 220 and 225 may be fluidly coupled by hose 230, 235 and Y-type fitting 240. Hose 232 may also be coupled to second end 223 of tube 220 via fitting 252 and coupled to Y-type fitting 245 via fitting 253. Hose 237 may also be coupled to second end 228 of tube 225 via fitting 256 and coupled to Y-type fitting 245 via fitting 257. Therefore, the second ends 223 and 228 of tubes 220 and 225 may be fluidly coupled by hose 232, 237 and Y-type fitting 245. Although illustrated as a Y-type fitting, the fitting can comprise any suitable three-way fitting arrangement, such as a T-type fitting, or in the context of a multi-pass strait through arrangement, a multi-port fitting comprising any suitable number of entrances/exits with a common fluid path.

Each of the hoses 230, 232, 235, and 237 may each comprise any suitable materials such as a non-electrically conductive material. Suitable non-electrically conductive materials include rubber, thermoplastic materials, fluoropolymers, silicon, and the like. The Y-type fittings 240 and 245 may comprise any suitable material such as a corrosion resistant metal or plastic material. For instance, the Y-type fittings 240/245 may comprise a corrosion resistant metal such as copper, galvanized steel, or brass, or alternatively, any suitable plastic-type material such as polyvinyl chloride (PVC), polypropylene (PP), polyethylene (PE), acrylonitrile butadiene styrene (ABS), polytetrafluoroethylene (PTFE), nylon.

The use of the hoses and Y-type fittings allows for easy serviceability of heat sink 201, where the hoses and/or Y-type fittings can easily be replaced if damaged or worn, and further allows for easy access to tubes 220 and 225 for cleaning and/or servicing. The ease of maintenance greatly reduces the down time associated with servicing/cleaning or replacement of parts or all of heat sinks 201.

Specifically, heat sink 201 may include couplings 250, 251, 252, 253, 254, 255, 256, and/or 257, which may be removeable couplings, such as spring-type couplings. The removeable couplings may be used to mechanically couple hoses 230, and 235, and 237 Y-type fitting 240 and hoses 232 and 237 to Y-type fitting 245. The use of removable/spring-type couplings enhance the serviceability/operability of heat sink 201. Specifically, since fittings 250, 251, 252, 253, 254, 255, 256, and/or 257 are removeable, hoses 230, 232, 235 and 237 can easily be decoupled from any one of tubes 220/225 or Y-type fittings 240/245, such that the tube(s) can easily be cleaned/replaced, the Y-type fitting(s) can easily be cleaned/replaced, and/or the hose(s) can be easily replaced.

Furthermore, spring-type fittings, and particularly spring-type clamp fittings, provide even force distribution on the connection points/hoses, which results in a lower likelihood that the fittings will loosen over time, lowering the probability that leaking will occur at the connections of the hoses 230, 232, 235 and/or 237 with tubes 220/225 and/or t-type fittings 240 and/or 245, as compared with other clamp designs, such as worm-type claims. In sum, since each of hoses 230, 232, 235 and 237; fittings 250, 251, 252, 253, 254, 255, 256, and/257; and Y-type fittings 240 and 245 are each designed as modular, easily replaceable units, the serviceability and cost of heats sink 201 is drastically increased.

Heat sink 201 may also include other features that enhance operability, such as threaded hole 260, where an external temperature sensor/switch can be attached. In this case, threaded hole 260 may be subtractively manufactured from body 210 via a similar process to passages 215/216. Integration of a temperature switch/sensor allows for constant monitoring of the temperature of heat sink 201, again enhancing the operability of heat sink 201 versus conventional heat sinks. Heat sink 210 may also include, although not illustrated, an equipment/component tag, which may be laser etched into body 210 of heat sink 201. Here, the equipment/component tag may include a serial number associated with heat sink 201, so that identification and subsequent monitoring of the unit is possible (e.g., to monitor specific units that fail, units that require frequent cleaning/service, etc.)

Heat sink 201 may be formed by a variety of methods based upon the foregoing discussion. For instance, body 210 of heat sink 201 may be cast, milled (e.g., precision milled), or otherwise formed into a given geometry. Thereafter, through holes are bored into and through the body 210 of material, forming passages 215 and 216. The boring process may be a precision boring process, whereas the low tolerance of diameters 217 and 218, as described previously, are met. Optionally, threaded hole 260 may be bored/tapped into body 210 at a given location about body 210. Tubes 220 and 225 are then formed by a separate process, such as a through-boring process, where rods of material are precision milled to a given external diameter 270 and 271 at the tight tolerances described previously, and through-bored to a nominal internal diameter. The ends of the tubes 220 and 225 may then be processed to form the barb type fittings 222, 224, 227, and 229. Tubes 220 and 225 then be fitted within passages 215 and 216 respectively, such as by pressing the tubes 220 and 225 into passages 215 and 216. Thereafter, hoses 230, 232, 235, and 237 may be coupled to barb-type fittings 222, 224, 227, and 229 at a first end, such as with fittings 250, 252, 254, and 256, and then affixed to Y-type fittings 240 and 245 at a second end, such as with fittings 251, 253, 255, 257. Thereafter, heat sink 201 may be put into commission, such as by heat sink 201 in thermal communication with (e.g., affixing to) a piece of high-power equipment, such as an SCR, and thereafter connecting the cooling fluid supply and return lines.

Although the foregoing discussion is described in view of heat sinks applied to SCRs used in electrolysis applications, such disclosure is non-limiting. For instance, the heat sink described in the present disclosure may be applied in numerous applicable scenarios where cooling of high-power electrical equipment is required.

For instance, heat sink 201 may alternatively be applied to high-power diodes or high heat load components in numerous other high power applications, but not limited to, motor drives, high-voltage regulation electric heating systems (e.g., induction heating, electric furnaces, etc.) power quality regulation systems (e.g., static var compensators (SVCs) and static synchronous compensators (STATCOMs)), high-power lighting control systems (e.g., stadiums or large event venue lighting), welding equipment using high welding current, high-voltage direct current (HVDC) power supplies, thyristor-controlled series capacitors (TCSC), and uninterruptible power supplies (UPS), and the like.

For instance, heat sink 201 may be applied to high-power electric equipment in power generation facilities, including, but not limited to, high-power electric equipment in steam power generation facilities, coal fired power plants, nuclear power plants, solar farms, and the like. Heat sink 201 may be additionally or alternatively be applied to high-power electric equipment in electrochemical platting facilities, induction forging facilities, and/or navel marine drives.

Therefore, the foregoing technology is equally applicable to any scenario where cooling for high power equipment such as rectifiers (including SCRs), thyristors, diodes, switches/motors, and the like is required, and including scenarios where AC to DC voltage transformation is required.

As described previously, heat sink 201 serves as a valid solution to the excess capitol cost and downtimes associated with replacement of heat sinks used in high power contexts. Therefore, heat sink 201 can be used in newly installed high-power equipment or may be retrofitted into existing equipment, replacing the corrosion/degradation prone existing heat sinks.

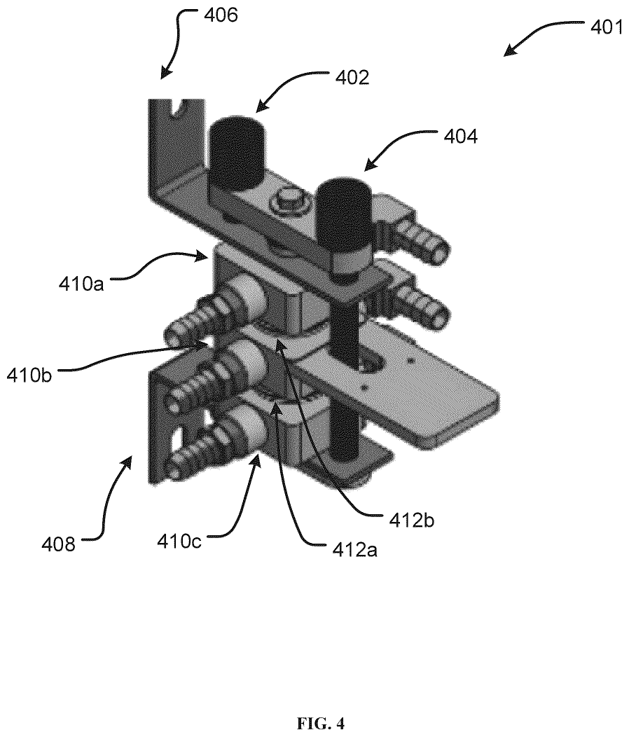

For instance, and as illustrated in FIG. 4, multiple heat sink 410s are arranged in a high-power electric assembly 401. The assembly includes mechanical attachment means 402 and 404, electrical busbars 406 and 408, one or more rectifiers 412 (e.g., 412a and 412b); and one or more heat sinks 410 (e.g., 410a, 410b, and 410c). Here, busbars 406 and 408 serve as the electrical connection points, providing an electric pathway for power distribution. The busbars 406 and 408 typically include a slotted connection, allowing for the busbars to accommodate different heights of high-power electrical assembly 401. High power electrical assembly 401 also includes mechanical attachment means 402 and 404 for joining (e.g., clamping together) the rectifiers 412 and chill blocks 410 between busbars 406 and 408.

High power electrical assembly 401 includes multiple rectifiers 412 and heat sinks 410. For instance, as illustrated, high power electrical assembly 401 includes two rectifiers 412a and 412b, positioned between (e.g., sandwiched between) three chill blocks 410a, 410b, and 410c. However, the disclosure is nonlimiting. For instance, any suitable number of chill blocks 412 and rectifiers 410 may be used.

As described previously, such as with reference to FIG. 1, traditional chill blocks, such as chill blocks 410 may be susceptible to galvanic corrosion as the metallurgies between the water, attachment points, and/or body of the chill blocks may be different. Therefore, high power electrical assembly 401 may either initially include, or may be retrofitted to include (e.g. the existing chill block 410s removed, and replaced) chill blocks 210 as described with reference to FIGS. 2 and 3. In the case of retrofitting, chill blocks 210 can easily replace chill blocks 410 via the steps of shutting down the high power electric equipment, (e.g., as according to the manufacturer's recommendations), referencing the manufacturer's maintenance manual for the removal procedure for the existing chill blocks 410 (e.g., such as decoupling the busbars 406 and 408 via the mechanical coupling 402 and 404, and removing each rectifiers 412 and chill blocks 410), installing the new chill block(s) 210, reassembling the high power electric equipment, coupling the inlets and outlets to the water suppl/return to/from each chill blocks 210, and restarting the high power electrical assembly 401. This process alleviates unnecessary complexity associated with retrofitting the chill blocks 210 of the present disclosure by utilizing known and convenient disassembly and reassembly procedures. Therefore, chill blocks 210 can find widespread applications in both new installation and existing retrofit contexts in the numerous industrial settings described previously.

### Examples

### Example 1: Thermal Performance of Double Pass, Strait Through Heat Sink

Thermal performance is evaluated for a double pass, strait through heat sink (e.g., substantially similar to FIG. 2) as compared to a single pass, complex geometry heat sink (e.g., substantially similar to FIG. 1) in both fouled and unfouled states. Here, each of the three heat sink embodiments are mounted to an SCR, and subsequently connected to cooling water. The cooling water is supplied under the same conditions to all three heat sinks, at an inlet temperature of 31.1° C. and a 0.1577 L/s flowrate. Outlet temperature (° C.) is recorded once steady state is achieved, and used to calculate the resulting heat transfer rate (W), as presented in Table 1 below.

TABLE 1
Thermal Performance of Compared Heat Sinks

| | | Cooling Water | Cooling Water | |
|---|---|---|---|---|
| | Cooling Water | Inlet Temp | Outlet Temp | Heat Transfer |
| | Flowrate (L/s) | (° C.) | (° C.) | Rate (W) |
| Double Pass Heat | 0.1577 | 31.1 | 90.5 | 31358 |
| Sink | | | | |
| Single Pass Heat Sink | 0.1577 | 31.1 | 87.7 | 29893 |
| (unfouled) | | | | |
| Single Pass Heat Sink | 0.1577 | 31.1 | 78.3 | <25000 |
| (Fouled) | | | | |

The thermal performance of the double pass, strait through heat sink is greater than either of the single pass, complex geometry heat sinks (e.g., in either the fouled or unfouled states). Specifically, the double pass, strait through heat sink attains a higher ΔT between the inlet and outlet of the cooling water, resulting in a higher heat transfer rate (W) between the SCR and double pass heat sink, as compared to either of the single pass heat sinks in the unfouled and fouled states.

### Example 2: Double Pass, Strait Through Heat Sink Used in High Power Electrical Equipment

### Context 1: Electrolytic Cell in Chemical Processing Facility.

A double pass, strait through heat sink (e.g., substantially similar to FIG. 2) is installed in a high-power electrical assembly (e.g., an electrolytic cell) in an industrial chemical processing facility (e.g., electrolytic oxidation of HF). The double pass, strait through heat sink performs equally as well, if not slightly exceeds the performance of a traditional heat sink in an unfouled state and outperforms a traditional heat sink in a fouled state in the high-power electrical assembly, exhibiting substantially similar results to Example 1. The double pass, strait through heat sink is tested in both a new installation, and a retrofit of existing heat sink context.

### Example 3: Double Pass, Strait Through Heat Sink Used in High Power Electrical Equipment

### Context 2: Power Generation Facility

A double pass, strait through heat sink (e.g., substantially similar to FIG. 2) is installed in a high-power electrical assembly in a power generation facility (e.g., as based upon steam/nuclear/coal fired/solar power generation). The double pass, strait through heat sink performs equally as well, if not slightly exceeds the performance of a traditional heat sink in an unfouled state and outperforms a traditional heat sink in a fouled state in the high-power electrical assembly, exhibiting substantially similar results to Example 1. The double pass, strait through heat sink is tested in both a new installation and in a retrofit of existing heat sink context.

### Example 4: Double Pass, Strait Through Heat Sink Used in High Power Electrical Equipment

### Context 3: Electrochemical Plating Facility

A double pass, strait through heat sink (e.g., substantially similar to FIG. 2) is installed in a high-power electrical assembly (e.g., rectifier) in an electrochemical plating facility. The double pass, strait through heat sink performs e equally as well, if not slightly exceeds the performance of a traditional heat sink in an unfouled state and outperforms a traditional heat sink in a fouled state in the high-power electrical assembly, exhibiting substantially similar results to Example 1. The double pass, strait through heat sink is tested in both a new installation and in a retrofit context.

### Example 5: Double Pass, Strait Through Heat Sink Used in High Power Electrical Equipment

### Context 4: Induction Forging Facility

A double pass, strait through heat sink (e.g., substantially similar to FIG. 2) is installed in a high-power electrical assembly (e.g., rectifier) in an induction forging facility. The double pass, strait through heat sink performs equally as well, if not slightly exceeds the performance of a traditional heat sink in an unfouled state and outperforms a traditional heat sink in a fouled state in the high-power electrical assembly, exhibiting substantially similar results to Example 1. The double pass, strait through heat sink is tested in both a new installation and in a retrofit context.

### Example 6: Double Pass, Strait Through Heat Sink Used in High Power Electrical Equipment

### Context 5: High Voltage AC to DC Conversion

A double pass, strait through heat sink (e.g., substantially similar to FIG. 2) is installed in a high-power electrical assembly for converting AC to DC power. The double pass, strait through heat sink performs equally as well, if not slightly exceeds the performance of a traditional heat sink in an unfouled state and outperforms a traditional heat sink in a fouled state in the high-power electrical assembly, exhibiting substantially similar results to Example 1. The double pass, strait through heat sink is tested in both a new installation and in a retrofit context.

### Example 7: Double Pass, Strait Through Heat Sink Used in High Power Electrical Equipment

### Context 6: Marine Drives

A double pass, strait through heat sink (e.g., substantially similar to FIG. 2) is installed in a high-power electrical assembly in a navel marine drive. The double pass, strait through heat sink performs equally as well, if not slightly exceeds the performance of a traditional heat sink in an unfouled state and outperforms a traditional heat sink in a fouled state in the high-power electrical assembly, exhibiting substantially similar results to Example 1. The double pass, strait through heat sink is tested in both a new installation and in a retrofit context.

### Aspects

Aspects of the present disclosure include Aspect 1. Aspect 1 is a heat exchange device for electrical applications comprising: a block comprising a thermally conductive material and including one or more passages disposed substantially parallel about a longitudinal axis of the block; and one or more tubes comprising a corrosion resistant material, different from the thermally conductive material, each of the one or more tubes disposed within a respective passage.

Aspect 2 is the heat exchange device of any preceding or subsequent aspect, wherein the block comprises two or more passages disposed in tandem about the longitudinal axis, and the heat exchange device comprises two or more tubes, each tube disposed within a respective passage.

Aspect 3 is the heat exchange device of any preceding or subsequent aspect, wherein each of the two or more tubes comprises a first end and a second end, each of the first ends and second ends extending from the respective passage.

Aspect 4 is the heat exchange device of any preceding or subsequent aspect, wherein the first end and the second end of each tube comprise a barb type structure.

Aspect 5 is the heat exchange device of any preceding or subsequent aspect, wherein the first ends of each of the two or more tubes are fluidly coupled to one another external to the passage of the body, and the second ends of each of the two or more tubes are fluidly coupled to one another external to the passage of the body.

Aspect 6 is the heat exchange device of any preceding or subsequent aspect, wherein the first ends are fluidly coupled to one another with a first multi-port fitting, and the second ends are coupled to one another with a second multi-port fitting.

Aspect 7 is the heat exchange device of any preceding or subsequent aspect, wherein each of the first end and the second end of each of the two or more tubes are fluidly coupled to a respective hose, each hose coupled to the respective end of the tube with a spring-type fitting.

Aspect 8 is the heat exchange device of any preceding or subsequent aspect, wherein the thermally conductive material comprises copper, silver, gold, platinum, and/or combinations and/or alloys thereof.

Aspect 9 is the heat exchange device of any preceding or subsequent aspect, wherein the thermally conductive material comprises copper.

Aspect 10 is the heat exchange device of any preceding or subsequent aspect, wherein the corrosion resistant material comprises and alloy comprising iron, chromium, and nickel.

Aspect 11 is the heat exchange device of any preceding or subsequent aspect, wherein the corrosion resistant material comprises 304 Stainless Steel.

Aspect 12 is the heat exchange device of any preceding or subsequent aspect, wherein the first multiport fitting and the second multiport fitting each comprise one of copper, galvanized steel, brass, or plastic.

Aspect 13 is the heat exchange device of any preceding or subsequent aspect, wherein the hoses comprise an insulative material comprising one of rubber, thermoplastic materials, fluoropolymers, and silicon.

Aspect 14 is the heat exchange device of any preceding or subsequent aspect, wherein all of the one or more passages and all of the one or more tubes do not comprise an anti-corrosive coating.

Aspect 15 is the heat exchange device of any preceding or subsequent aspect, wherein each passage comprises an internal diameter, and each tube comprises an external diameter, the external diameter of the respective tube less than the internal diameter of the respective passage within 0.01 cm to .0001 cm.

Aspect 16 is the heat exchange device of any preceding or subsequent aspect, wherein the body comprises a rectangular prism geometry.

Aspect 17 is an electrical equipment system comprising: a heat-generating electrical component; and a heat sink in thermal communication with the electrical component, the heat sink comprising: a body comprising a thermally conductive material and including two passages arranged in tandem and disposed substantially parallel about a longitudinal axis of the body; and two tubes comprising a corrosion resistant material, different from the thermally conductive material, each of the two tubes disposed within a respective passage and extending from the respective passage at a first end and a second end, each of the first ends and the second ends in fluid communication external to the body of the heat sink.

Aspect 18 is an electrical equipment system of any preceding or subsequent aspect, wherein the first end of each of the two tubes are fluidly coupled to a respective hose, each of the two hoses fluidly coupled by a first three-way fitting configured to supply a cooling fluid, and the second end of each of the two tubes are fluidly coupled to a respective hose, each of the two hoses fluidly coupled by a second three-way fitting configured to return the cooling fluid.

Aspect 19 is an electrical equipment system of any preceding or subsequent aspect, wherein the electrical component comprises one of a diode or thyristor.

Aspect 20 is an electrical equipment system of any preceding or subsequent aspect, wherein the two passages and the two tubes lack a coating applied to any portion of the passages and two tubes.

Aspect 21 is the electrical equipment system of any one of Aspects 15-20, wherein the heat sink comprises the exchange device of any one of aspects 1-15.

Aspect 22 is the electrical equipment system of any one of Aspects 15-21, wherein the heat-generating electrical component comprises any one of or combination of a diode, a thyristor, a rectifier, an AC-DC power converter, and/or a motor drive.

Aspect 23 is the electrical equipment system of any one of Aspects 15-22, wherein the heat-generating electrical component is utilized in a chemical processing facility,

Aspect 24 is the electrical equipment system of any one of Aspects 15-22, wherein the heat-generating electrical component is utilized in a power generation facility,

Aspect 25 is the electrical equipment system of any one of Aspects 15-22, wherein the heat-generating electrical component is utilized in an electrochemical plating facility,

Aspect 26 is the electrical equipment system of any one of Aspects 15-22, wherein the heat-generating electrical component is utilized in an induction forging facility,

Aspect 27 is the electrical equipment system of any one of Aspects 15-22, wherein the heat-generating electrical component is utilized for high voltage transformation.

Aspect 28 is the electrical equipment system of any one of Aspects 15-22, wherein the heat-generating electrical component is utilized in a naval marine drive.

1. A heat exchange device for electrical applications comprising:
a body comprising a thermally conductive material and including one or more passages disposed substantially parallel about a longitudinal axis of the body; and
one or more tubes comprising a corrosion resistant material, different from the thermally conductive material, each of the one or more tubes disposed within a respective passage.

2. The heat exchange device of claim 1, wherein the body comprises two or more passages disposed in tandem about the longitudinal axis, and the heat exchange device comprises two or more tubes, each tube disposed within a respective passage.

3. The heat exchange device of claim 2, wherein each of the two or more tubes comprises a first end and a second end, each of the first ends and second ends extending from the respective passage.

4. The heat exchange device of claim 3, wherein the first end and the second end of each tube comprise a barb type structure.

5. The heat exchange device of claim 3, wherein the first ends of each of the two or more tubes are fluidly coupled to one another external to the passage of the body, and the second ends of each of the two or more tubes are fluidly coupled to one another external to the passage of the body.

6. The heat exchange device of claim 5, wherein the first ends are fluidly coupled to one another with a first multi-port fitting, and the second ends are coupled to one another with a second multi-port fitting.

7. The heat exchange device of claim 6, wherein the first multiport fitting and the second multiport fitting each comprise one of copper, galvanized steel, brass, or plastic.

8. The heat exchange device of claim 5, wherein each of the first end and the second end of each of the two or more tubes are fluidly coupled to a respective hose, each hose coupled to the respective end of the tube with a spring-type fitting.

9. The heat exchange device of claim 8, wherein the hoses comprise an insulative material comprising one of rubber, thermoplastic materials, fluoropolymers, and silicon.

10. The heat exchange device of claim 1 wherein the thermally conductive material comprises copper, silver, gold, platinum, and/or combinations and/or alloys thereof.

11. The heat exchange device of claim 1, wherein the thermally conductive material comprises copper.

12. The heat exchange device of claim 1, wherein the corrosion resistant material comprises and alloy comprising iron, chromium, and nickel.

13. The heat exchange device of claim 1, wherein the corrosion resistant material comprises 304 Stainless Steel.

14. The heat exchange device of claim 1, wherein all of the one or more passages and all of the one or more tubes do not comprise an anti-corrosive coating.

15. The heat exchange device of claim 1, wherein each passage comprises an internal diameter, and each tube comprises an external diameter, the external diameter of the respective tube less than the internal diameter of the respective passage within 0.01 cm to .0001 cm.

16. The heat exchange device of claim 1, wherein the body comprises a rectangular prism geometry.

17. An electrical equipment system comprising:
a heat-generating electrical component; and
a heat sink in thermal communication with the electrical component, the heat sink comprising:
a body comprising a thermally conductive material and including two passages arranged in tandem and disposed substantially parallel about a longitudinal axis of the body; and
two tubes comprising a corrosion resistant material, different from the thermally conductive material, each of the two tubes disposed within a respective passage and extending from the respective passage at a first end and a second end, each of the first ends and the second ends in fluid communication external to the body of the heat sink.

18. The electrical equipment system of claim 17, wherein
the first end of each of the two tubes are fluidly coupled to a respective hose, each of the two hoses fluidly coupled by a first three-way fitting configured to supply a cooling fluid, and
the second end of each of the two tubes are fluidly coupled to a respective hose, each of the two hoses fluidly coupled by a second three-way fitting configured to return the cooling fluid.

19. The electrical equipment system of claim 17, wherein the electrical component comprises one of a diode or thyristor.

20. The electrical equipment system of claim 17, wherein the electrical equipment system is employed in any one of a chemical processing facility, a power generation facility, an electrochemical plating facility, an induction forging facility, a high voltage transformation device, and a naval marine drive.
